(19) United States
(12) Patent Application Publication
(10) Pub. No.: US 2014/0083841 A1
(43) Pub. Date: Mar. 27, 2014

(54) THIN FILM-FORMING METHOD

(71) Applicants: Yoshifumi Ohta, Osaka (JP); Yoshimasa Chikama, Osaka (JP)

(72) Inventors: Yoshifumi Ohta, Osaka (JP); Yoshimasa Chikama, Osaka (JP)

(73) Assignee: SHARP KABUSHIKI KAISHA, Osaka (JP)

(21) Appl. No.: 14/116,745

(22) PCT Filed: May 7, 2012
(86) PCT No.: PCT/JP2012/002992

§ 371 Date: Nov. 8, 2013

(30) Foreign Application Priority Data
May 13, 2011 (JP) 2011-108140

(51) Int. Cl. C23C 14/34

(52) U.S. Cl. CPC C23C 14/3492
USPC 204/192.25; 204/192.12

(57) ABSTRACT

A method of forming a thin-film includes: a normal deposition step of depositing a thin-film on a substrate by performing discharge among a plurality of targets, and by providing an inert gas and a reactive gas into a processing chamber, with a magnet section being reciprocated along a target section formed by these targets; and a discharge starting step of starting a discharge at the target section prior to the normal deposition step, in a state in which a flow ratio of the reactive gas to the inert gas is larger than a flow ratio of the reactive gas to the inert gas in the normal deposition step.

### TECHNICAL FIELD

The present invention relates to a method of forming a thin-film.

### BACKGROUND ART

Sputtering is commonly known as a method to form a thin-film on a substrate surface. The sputtering method is widely known as a dry process technique indispensable in film forming techniques. The sputtering method is a method of film deposition in which a noble gas such as Ar is introduced into a vacuum container, and direct current (DC) power or radio frequency (RF) power is supplied to a cathode that includes a target, thus generating a glow discharge.

The sputtering method includes a magnetron sputtering method in which a magnet is disposed on the rear of a target in an electrically grounded chamber, which increases the concentration of plasma in the vicinity of the target surface, thereby allowing film deposition to be conducted quickly. Such a sputtering method is used in forming a prescribed thin-film on a processed substrate with a large area, such as a glass substrate forming a liquid crystal display panel or the like, for example.

A method is disclosed in Patent Document 1 relating to a magnetron sputtering device in which a substrate to be processed and a plurality of targets are arranged at prescribed gaps, and then a prescribed frequency is used to alternate polarity in order to apply alternating current voltage to the respective targets, for example. A glow discharge is released while alternating the anode electrodes and cathode electrodes between adjacent pairs of the targets, thereby forming a plasma atmosphere.

However, in a sputtering device disclosed in Patent Document 2, a magnetron sputtering device having a plurality of targets that have the same polarity of voltage as each other respectively applied thereto moves a substrate in parallel with the targets.

### RELATED ART DOCUMENTS

### Patent Documents

Patent Document 1: Japanese Patent Application Laid-Open Publication No. 2003-96561

Patent Document 2: Japanese Translation of PCT International Application Publication No. WO 2008/108185

### SUMMARY OF THE INVENTION

### Problems to be Solved by the Invention

In the sputtering device in Patent Document 1 described above, prescribed gaps are provided between the respective adjacent targets, and thus, there is a risk that the film quality of the thin-film to be sputtered will be different among regions facing the targets and regions facing the gaps between the targets. It is possible to make the film quality of the thin-film to be formed on the substrate uniform by moving the substrate with respect to the targets, as in Patent Document 2 described above.

However, as a result of diligent and continuous research into forming thin-films by sputtering, the inventors of the present invention have found that it is easy for abnormalities to occur in the film quality of thin-films formed between electrodes during the start of discharge. Accordingly, it is actually difficult to make the film quality of the formed thin-films uniform by merely moving the substrate with respect to the targets as in Patent Document 2 described above.

The present invention was made in view of the above, and aims at increasing the film quality of thin-film formed by sputtering as much as possible.

### Means for Solving the Problems

To achieve the above-mentioned aim, a method of forming a thin-film according to the present invention includes: a normal deposition step of depositing a thin-film on a substrate in a processing chamber by performing discharge among a plurality of targets that are arranged parallel to the substrate at prescribed gaps, and by providing an inert gas and a reactive gas to the processing chamber, the targets constituting a target section that is arranged facing the substrate to be processed, the discharge being performed when a magnet section is reciprocated along the target section; and a discharge starting step of starting discharge in the target section prior to the normal deposition step, in a state in which a flow ratio of the reactive gas to the inert gas is larger than a flow ratio of the reactive gas to the inert gas during the normal deposition step.

As a result of diligent and continuous research into forming thin-films by sputtering, the inventors of the prevent invention have found that variation in film quality of thin-film occurs in substrate regions facing gaps between the targets and substrate regions facing the targets, due to the discharge state becoming unstable when discharge at the targets is started.

According to the configuration described above, a thin-film is formed on the substrate in the normal deposition step by supplying an inert gas and a reactive gas into a processing chamber and performing discharge between the targets of the target section. The discharge starting step is performed before the normal deposition step, and the discharge state is able to be stabilized at the start of the discharge by making the flow ratio of the reactive gas to the inert gas larger than the same flow ratio in the normal deposition step. In this way, variation in film quality of the thin-film in substrate regions facing the gap between the targets and the substrate regions facing the targets can be suppressed to substantially increase the film quality of the thin-film formed on the entire substrate by sputtering.

After the normal deposition step, the method may include an ending preparation step of performing discharge on the target section, in a state in which the flow ratio of the reactive gas to the inert gas is larger than the flow ratio of the reactive gas to the inert gas in the normal deposition step.

According to research done by the inventors of the present invention, the discharge state also becomes unstable at the target section for a prescribed time until discharge is ended, and variation in film quality of the thin-film occurs in substrate regions facing the gaps between the targets and substrate regions facing the targets.

According to the above configuration, the flow ratio of active gas to inert gas in the ending preparation step is larger than the same flow ratio in the normal deposition step, thereby making it possible to stabilize the discharge state in this ending preparation step. Thus, variation in the film quality of the thin-film formed on the substrate can be reduced in order to more precisely increase the film quality.

### Effects of the Invention

According to the present invention, the flow ratio of reactive gas to inert gas during the discharge starting period is larger than the same flow ratio in the normal deposition period, thereby allowing the discharge state during the discharge starting period to be stabilized. Therefore, variation in film quality of thin-film in substrate regions facing the gaps between the targets and substrate regions facing the targets can be suppressed. As a result, the film quality of thin-film formed on the entire substrate by sputtering can be substantially increased.

### BRIEF DESCRIPTION OF THE DRAWINGS

FIG. 1 is a cross-sectional view that shows a schematic configuration of a thin-film forming device according to Embodiment 1.

FIG. 2 is a graph showing changes of gas flow over time in Embodiment 1.

FIG. 3 is a graph showing changes of gas flow over time in Embodiment 2.

FIG. 4 is a graph showing changes of gas flow over time in a comparison example.

FIG. 5 is a graph showing characteristics of a TFT having an oxide semiconductor film that is formed using the method of forming a thin-film in the comparison example.

FIG. 6 is a graph showing a relationship between peak strength and wavelength in a CL spectrum in the comparison example.

FIG. 7 is a graph comparatively showing peak strength in a CL spectrum above cathodes and between cathodes in the comparison example.

FIG. 8 is a graph comparatively showing peak strength in a CL spectrum above cathodes and between cathodes in an example.

FIG. 9 is a graph showing a relationship between measurement location of a thin-film formed on a substrate and sheet resistance in the comparison example.

FIG. 10 is a graph showing a relationship between measurement location of a thin-film formed on a substrate and sheet resistance in the example.

FIG. 11 is a graph showing changes of gas flow over time in Embodiment 3.

FIG. 12 is a graph showing changes of gas flow over time in Embodiment 4.

FIG. 13 is a graph showing changes of gas flow over time in Embodiment 5.

### DETAILED DESCRIPTION OF EMBODIMENTS

Embodiments of the present invention will be described in detail below with reference to drawings. The present invention is not limited to the embodiments below.

### Embodiment 1

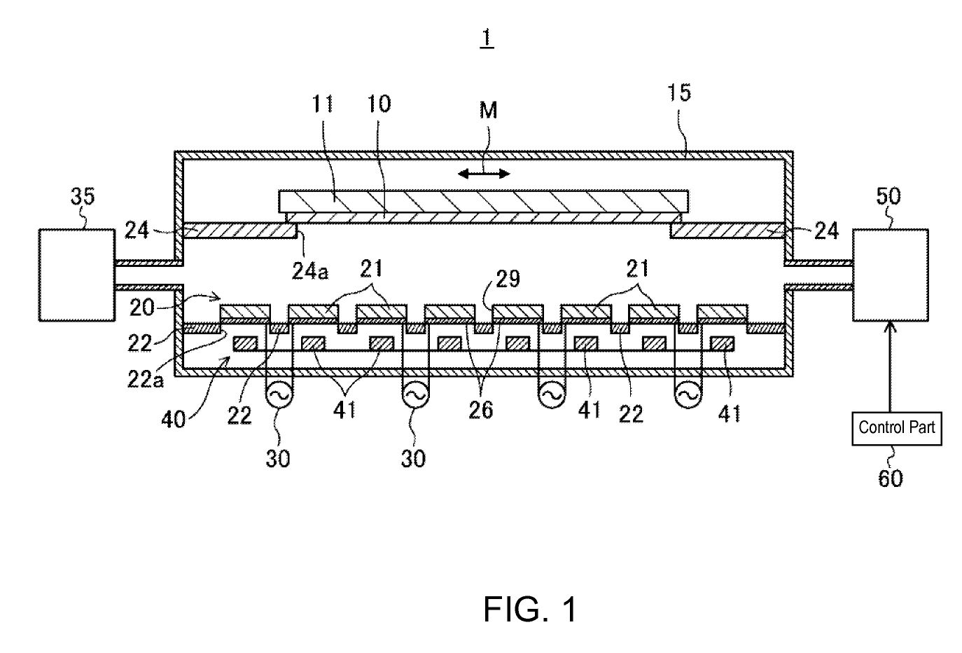

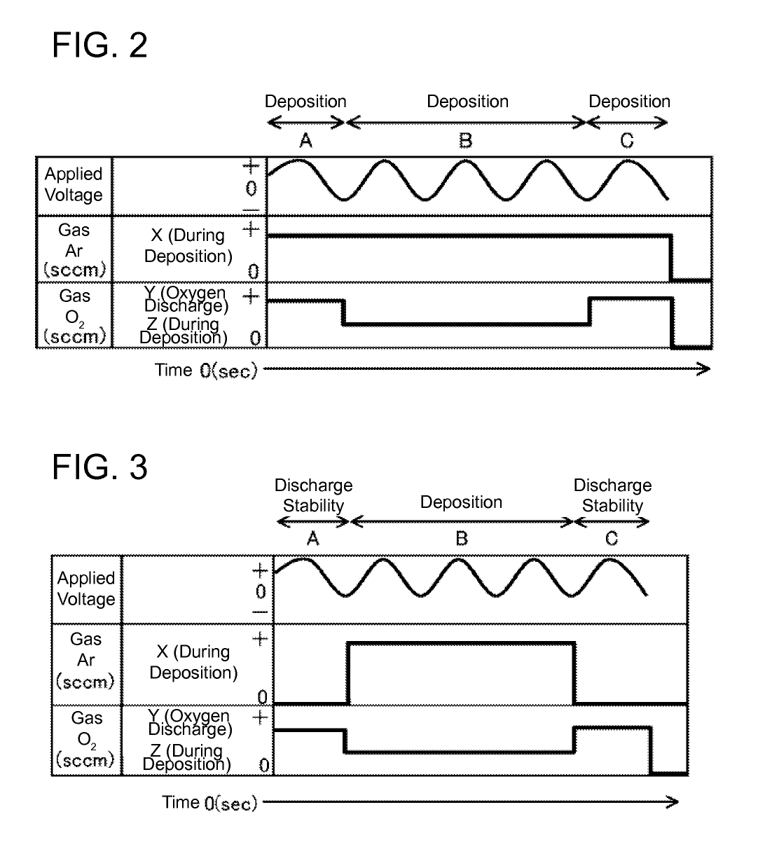

FIGS. 1 and 2 show Embodiment 1 of the present invention.

FIG. 1 is a cross-sectional view that shows a schematic configuration of a thin-film forming device 1 according to Embodiment 1. FIG. 2 is a graph showing changes of gas flow over time in Embodiment 1.

As shown in FIG. 1, the magnetron sputtering device 1 of Embodiment 1, which is a thin-film forming device, is provided with: a substrate holding part 11 that holds a substrate 10; a target section 20 arranged so as to face the substrate 10 to be processed, the substrate being held by the substrate holding part 11; power sources 30 that supply power to the target section 20; a magnet section 40 arranged to the rear of the target section 20, the rear being the side of the target section 20 that is opposite to the side facing the substrate 10; and a processing chamber 15 that internally houses the substrate holding part 11, the target section 20, and the magnet section 40.

The processing chamber 15 is a vacuum chamber in which the walls thereof are electrically grounded. A vacuum pump 35 is connected to the processing chamber 15, and the inside of the processing chamber 15 is depressurized by the vacuum pump 35.

A gas supply part 50 is connected to the processing chamber 15. The gas supply part 50 supplies at least reactive gas among inert gas (Ar gas or the like, for example) and reactive gas (O₂ gas or the like, for example) to the processing chamber 15 in a vacuum state.

The substrate 10 is a glass substrate or the like of a liquid crystal display panel (not shown), for example. The substrate 10 has a vertical length of around 730 mm and a horizontal length of around 920 mm, for example. The substrate holding part 11 holds the substrate 10 on the lower surface thereof, and has a heater (not shown) that heats the substrate 10 during film deposition. A substrate mask 24 that covers outer edges of the lower surface of the substrate 10 is provided in the processing chamber 15. The substrate mask 24 is for preventing unnecessary sputtering particles from attaching to the substrate 10 and processing chamber 15. The substrate mask 24 has a rectangular opening 24a in the center thereof.

As shown in FIG. 1, the target section 20 has a plurality of targets 21 arranged at prescribed gaps in parallel to the substrate 10 that is being held by the substrate holding part 11. The respective targets 21 are formed in a rectangular plate shape, and are arranged in parallel to each other in a prescribed direction (the horizontal direction in FIG. 1) such that the long sides thereof are mutually adjacent. The targets 21 are respectively arranged with a prescribed gap therebetween in the movement direction of the magnet section 40, which will be described later.

The targets 21 are made of a material that includes an oxide semiconductor such as IGZO (In-Ga-ZnO₄; amorphous oxide semiconductor) or the like, for example. The composition ratio of In, Ga, and Zn in the targets 21 is 1:1:1, for example. The targets 21 may be made of another material, such as another semiconductor material, metal material, or ITO (indium tin oxide). The respective targets 21 are formed in a rectangular plate shape of around 200 mm×3400 mm, for example.

The respective targets 21 are supported by target support parts 22 via backing plates 26. The backing plates 26 are made of a conductive material such as a metal material, and cool the targets 21 during sputtering. The backing plates 26 are joined with the targets 21 via a bonding material such as indium or tin.

The target support parts 22 are made of an insulating material, and fixed to the processing chamber 15. A plurality of openings 22a are formed in the target support parts 22 in positions corresponding to the respective targets 21. As shown in FIG. 1, the targets 21 and backing plates 26 are arranged corresponding to the respective openings 22a.

One alternating current power source 30 is connected to each pair of mutually adjacent targets 21. The frequency of the drive voltage (cathode voltage) of the power sources 30 is approximately 19 kHz to 20 kHz, for example. The driving power is around 10 to 90 kW.

The magnet section 40 is configured to reciprocate along the rear side of the target section 20 by a drive mechanism not shown in the drawing. As shown in FIG. 1, the magnet section 40 has a plurality of magnets 41 disposed with a prescribed gap therebetween in the movement direction of the magnet section 40 (the horizontal direction in FIG. 1). The respective magnets 41 are provided in positions corresponding to the respective targets 21, and are constituted by permanent magnets. The respective magnets 41 are formed into a rectangular plate shape of around 100 mm×3350 mm, for example. The width of the movement direction of the magnets 41 is smaller than the width of the targets 21 in the movement direction.

The respective magnets 41 oscillate synchronously with each other. The oscillation speed is approximately 10 mm/s to 30 mm/s, for example.

The substrate holding part 11 moves the substrate 10 being held by this substrate holding part 11 parallel to the target section 20 by a roller mechanism or the like, for example. As shown by the arrow M in FIG. 1, the substrate holding part 11 reciprocates the substrate 10 in the horizontal direction.

In the magnetron sputtering device 1 described above, a prescribed frequency is used to alternately change polarity in order to apply alternating current voltage to the respective targets 21 from the respective power sources 30, and a glow discharge is released while alternating the anode electrodes and cathode electrodes between adjacent pairs of the targets 21, thereby forming a plasma atmosphere inside the processing chamber 15. This plasma causes Ar ions to collide with the targets 21, thereby making sputtered particles fly off towards the substrate 10 from the targets 21. This deposits a film onto the surface of the substrate 10.

The magnetron sputtering device 1 described above is provided with a control part 60 that controls the gas supply part 50. As shown in FIG. 2, the control part 60 controls the gas supply part 50 such that the flow ratio of O₂ gas, as the reactive gas, to Ar gas, as the inert gas, in a discharge starting period A when discharge has started at the target section 20 becomes larger than the flow ratio of O₂ gas to Ar gas in a normal deposition period B after the discharge starting period A.

Furthermore, as shown in FIG. 2, the control part 60 increases the flow ratio of O₂ gas to Ar gas in a ending preparation period C, which is the period from after the normal deposition period B until discharge at the target section 20 ends, so that this ratio is larger than the flow ratio of O₂ gas to Ar gas in the normal deposition period B.

In other words, as shown in FIG. 2 the control part 60 consistently maintains the flow of Ar gas during the discharge starting period A, the normal deposition period B, and the ending preparation period C. The control part 60 increases the flow of O₂ gas in the discharge starting period A and ending preparation period C to be greater than the flow of O₂ gas in the normal deposition period B.

-Method of Forming a Thin-Film-

Next, a method will be explained to form an oxide semiconductor film as a thin-film on the substrate 10 using the magnetron sputtering device 1 as described above.

When film deposition is conducted on the substrate 10 by the magnetron sputtering device 1, first, the substrate 10, which is a glass substrate, is brought into the processing chamber 15 and held by the substrate holding part 11. Next, the inside of the processing chamber 15 is depressurized by a vacuum pump (not shown), and the substrate 10 is heated by a heater (not shown) in the substrate holding part 11. The targets 21 are made of a material that includes IGZO (In-Ga-ZnO₄; amorphous oxide semiconductor), for example.

The method of forming a thin-film in the present embodiment includes the discharge starting step conducted during the discharge starting period A, the normal deposition step conducted during the normal deposition period B, and the ending preparation step conducted during the ending preparation period C. Deposition is conducted throughout the discharge starting step, normal deposition step, and ending preparation step.

(Discharge Starting Step)

Next, in the discharge starting step, discharge at the target section 20 is started in a state in which a high vacuum is maintained while the control part 60 controls the gas supply part 50 in order to make the flow ratio of O₂ gas, the reactive gas, to Ar gas, the inert gas, greater than the flow ratio of O₂ gas to Ar gas in the normal deposition step, which comes after the discharge starting step.

In other words, as shown in FIG. 2, in the discharge starting period A, a prescribed flow of Ar gas is supplied to inside the processing chamber 15 from the gas supply part 50, which is controlled by the control part 60. This flow is greater than the flow of O₂ gas that will be supplied to inside the processing chamber 15 in the following normal deposition step. The flow of Ar gas is maintained at a constant level throughout the discharge starting step, normal deposition step, and ending preparation step.

Power is supplied to the target section 20 by applying a prescribed alternating current voltage from the power sources 30, and the magnet section 40 is oscillated. The oscillation speed of the magnet section 40 is approximately 10 mm/s to 30 mm/s, for example. The substrate 10 that is held by the substrate holding part 11 is reciprocated in the M direction in FIG. 1.

In this way, a glow discharge is released between the mutually adjacent targets 21 to generate plasma on the side of the substrate 10 near the target section 20. In this discharge starting step, the flow ratio of O₂ gas to Ar gas is larger than the same flow ratio in the normal deposition step, and thus the discharge state is stabilized with ease.

Ar that has become positively ionized due to the plasma is drawn to the target section 20. The Ar ions collide with each target 21 causing sputtered particles that constitute the targets 21 to fly off towards the substrate 10. The sputtered particles that fly off from the targets 21 towards the substrate 10 bond and accumulate on the surface of the substrate 10. Thus, an In-Ga-ZnO₄ thin-film is formed on the substrate 10.

(Normal Deposition Step)

Next, in the normal deposition step, the flow ratio of the respective gases supplied by the gas supply part 50 is changed by the control part 60, while the reciprocating of the magnets 41 and substrate 10 and the discharge at the target section 20 continue in a similar manner to the discharge starting step.

In other words, as shown in FIG. 2, in the normal deposition period B, Ar gas is supplied to inside the processing chamber 15 from the gas supply part 50 controlled by the control part 60 with the same flow as the discharge starting step. However, O₂ gas is supplied to inside the processing chamber 15 in a flow that is less than the discharge starting step. Accordingly, in this normal deposition step, the flow ratio of O₂ gas to Ar gas is smaller than the flow ratio in the discharge starting step.

Thus, in the normal deposition step, deposition of the In-Ga-ZnO₄ film by sputtering is conducted efficiently and precisely in a discharge state that has been stabilized by the discharge starting step.

(Ending Preparation Step)

Next, in the ending preparation step, the flow ratio of the respective gases supplied by the gas supply part 50 is changed by the control part 60, while the reciprocating of the magnets 41 and substrate 10 and the discharge at the target section 20 are continued in a manner similar to the normal deposition step.

In other words, as shown in FIG. 2, in the ending preparation period C, Ar gas is supplied to inside the processing chamber 15 from the gas supply part 50 controlled by the control part 60 with the same flow as the discharge starting step and normal deposition step. However, O₂ gas is supplied to inside the processing chamber 15 at a flow that is greater than the flow of O₂ gas in the normal deposition step. The flow of O₂ gas is the same in the ending preparation step as in the discharge starting step.

In this way, in the ending preparation step, discharge is conducted at the target section 20 while the flow ratio of O₂ gas to Ar gas is larger than the flow ratio of O₂ gas to Ar gas in the normal deposition step. This stabilizes the discharge state at the target section 20.

Afterwards, as shown in FIG. 2, the supplying of Ar gas and O₂ gas to the processing chamber 15 is stopped and deposition processing ends.

-Effects of Embodiment 1-

Therefore, according to Embodiment 1, the discharge state in the discharge starting period A can be stabilized due to the flow ratio of O₂ gas to Ar gas in the discharge starting period A being larger than the same flow ratio in the normal deposition period B. As a result, variation in film quality of the thin-film can be suppressed in regions of the substrate 10 facing the gaps between the targets 21 and regions of the substrate 10 facing the targets 21.

The discharge state in the ending preparation period C can also be stabilized because the flow ratio of O₂ gas to Ar gas in the ending preparation period C is larger than the same flow ratio in the normal deposition period B, in a manner similar to the discharge starting period A. As a result, variation in film quality of the thin-film formed on the substrate 10 can be reduced, and thus the film quality of the thin-film formed on the entire substrate 10 by sputtering is able to be substantially increased

In particular, in an oxide semiconductor film such as In-Ga-ZnO₄, variation in the film quality thereof has a large effect on characteristics of TFTs that have the oxide semiconductor film as a semiconductive layer. Accordingly, a film quality with an even higher degree of uniformity is needed for such an oxide semiconductor film. As a measure to address this, in the present embodiment, an In-Ga-ZnO₄ film with suppressed variation in film quality can be deposited while the discharge state is stabilized. Thus, the characteristics of a TFT using the In-Ga-ZnO₄ film formed by the method of forming a thin-film of the present embodiment can be significantly increased.

### Embodiment 2

FIG. 3 shows Embodiment 2 of the present invention.

FIG. 3 is a graph showing changes of gas flow over time in Embodiment 2. In each following embodiment below, parts that are the same as FIGS. 1 and 2 are assigned the same reference characters and detailed descriptions thereof will be omitted.

Embodiment 2 differs from Embodiment 1 in that the flow of Ar gas changes, whereas in Embodiment 1 the flow of Ar gas is maintained at a constant level throughout the discharge starting period A, normal deposition period B, and ending preparation period C.

In other words, a control part 60 in the present embodiment makes the flow of O₂ gas in a discharge starting period A greater than the flow of O₂ gas in a normal deposition period B, and makes the flow of Ar gas in the discharge starting period A less than the flow of Ar gas in the normal deposition period B.

In particular, as shown in FIG. 3, in the discharge starting period A the control part 60 of the present embodiment controls a gas supply part 50 such that O₂ gas is supplied to a processing chamber 15 while the Ar gas is not being supplied.

-Method of Forming a Thin-Film-

Next, a method will be explained to form a thin-film on a substrate 10 using a magnetron sputtering device 1 of the present embodiment.

The method of forming a thin-film in the present embodiment includes the discharge starting step conducted during the discharge starting period A, the normal deposition step conducted during the normal deposition period B, and the ending preparation step conducted during the ending preparation period C. Deposition is only conducted during the normal deposition step.

(Discharge Starting Step)

As shown in FIG. 3, in the discharge starting step, discharge at a target section 20 is started in a state in which a high vacuum is maintained while the control part 60 controls the gas supply part 50 in order to make the flow ratio of O₂ gas, the reactive gas, to Ar gas, the inert gas, greater than the flow ratio of O₂ gas to Ar gas in the normal deposition step.

In other words, as shown in FIG. 3, in the discharge starting period A, O₂ gas is supplied to the processing chamber 15 from the gas supply part 50 controlled by the control part 60 while the Ar gas is not being supplied.

Power is supplied to the target section 20 by applying a prescribed alternating current voltage from power sources 30, and a magnet section 40 is oscillated. The oscillation speed of the magnet section 40 is approximately 10 mm/s to 30 mm/s, for example. The substrate 10 that is held by a substrate holding part 11 is reciprocated in the M direction in FIG. 1.

In this way, a glow discharge is released between mutually adjacent targets 21 to generate plasma on the side of the substrate 10 near the target section 20. In this discharge starting step, the discharge state is stabilized with further ease because only the O₂ gas is supplied to the processing chamber 15 while the Ar gas is not being supplied. The thin-film is not formed on the substrate 10 in this discharge starting step.

(Normal Deposition Step)

Next, in the normal deposition step, the flow ratio of the respective gases supplied by the gas supply part 50 is changed by the control part 60, while the reciprocating of the magnets 41 and substrate 10 and the discharge at the target section 20 are continued.

In other words, as shown in FIG. 3, in the normal deposition period B a prescribed flow of Ar gas is supplied to inside the processing chamber 15 from the gas supply part 50 controlled by the control part 60. However, O₂ gas is supplied to inside the processing chamber 15 at a flow that is less than the discharge starting step. Accordingly, in this normal deposition step, the flow ratio of O₂ gas to Ar gas is smaller than the flow ratio in the discharge starting step.

Thus, in the normal deposition step, deposition of the In-Ga-ZnO₄ film by sputtering is conducted efficiently and precisely in a discharge state that has been stabilized by the discharge starting step.

(Ending Preparation Step)

Next, in the ending preparation step, the flow ratio of the respective gases supplied by the gas supply part 50 is changed by the control part 60, while the reciprocating of the magnets 41 and substrate 10 and the discharge at the target section 20 are continued.

In other words, as shown in FIG. 3, in the ending preparation period C, O₂ gas is supplied from the gas supply part 50 controlled by the control part 60 to the processing chamber 15, while the Ar gas is not being supplied, in a flow that is greater than the flow of O₂ gas during the normal deposition step, in a manner similar to the discharge starting step.

In this way, in the ending preparation step, discharge is conducted at the target section 20 while only O₂ gas is supplied to the processing chamber 15 and while the flow ratio of O₂ gas to Ar gas is larger than the flow ratio of O₂ gas to Ar gas in the normal deposition step. This stabilizes the discharge state at the target section 20.

-Effects of Embodiment 2-

Therefore, according to Embodiment 2, the discharge state in the discharge starting period A can be stabilized by the flow ratio of O₂ gas to Ar gas in the discharge starting period A being larger than the same flow ratio in the normal deposition period B. Furthermore, the discharge state in the ending preparation period C can also be stabilized because the flow ratio of O₂ gas to Ar gas in the ending preparation period C is larger than the same flow ratio in the normal deposition period B, in a manner similar to the discharge starting period A.

As a result, variation in film quality of the thin-film can be suitably suppressed in regions of the substrate 10 facing the gaps between the targets 21 and regions of the substrate 10 facing the targets 21, resulting in the film quality of the thin-film formed on the entire substrate 10 by sputtering being able to be substantially increased

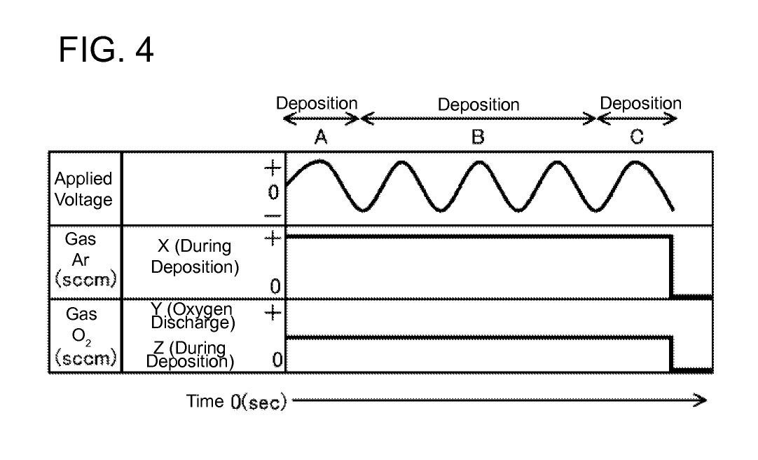

A comparison example that does not have the control part 60 will be explained with reference to FIGS. 4 to 7 and FIG. 9.

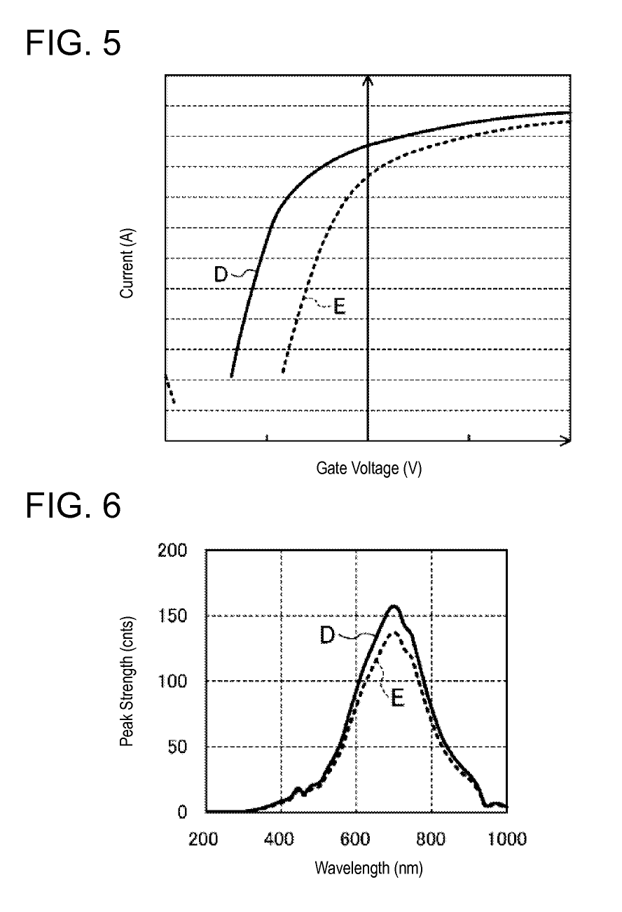

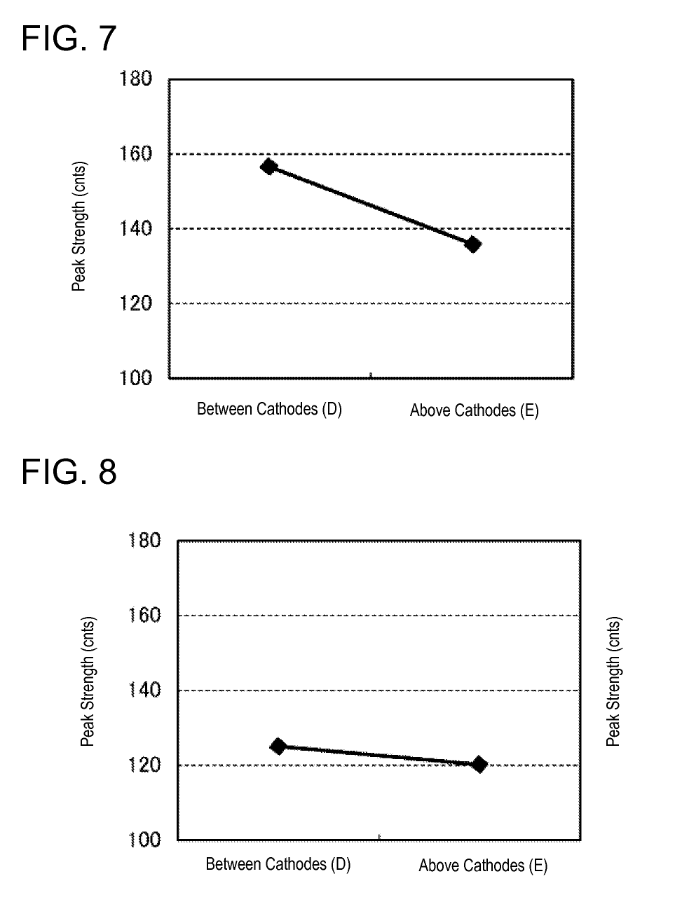

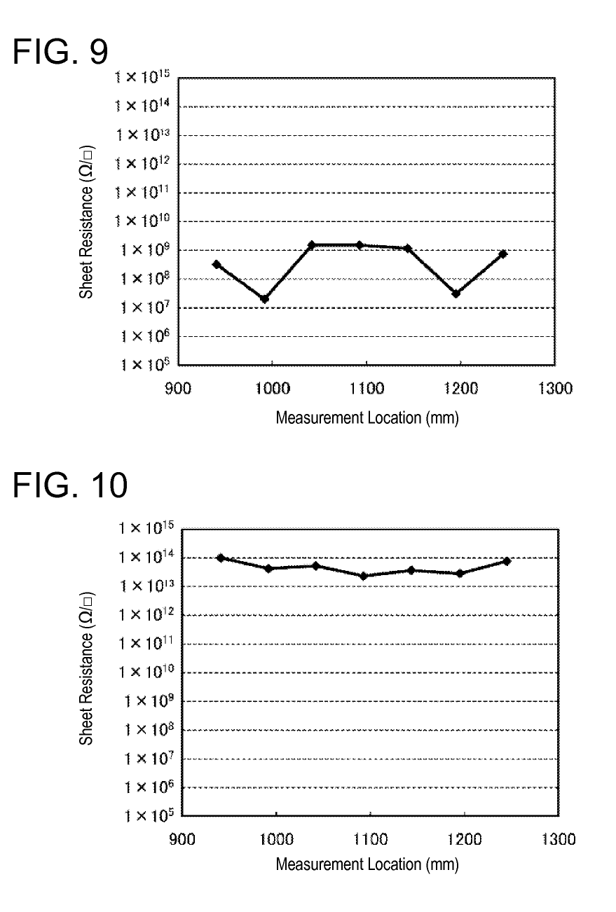

FIG. 4 is a graph showing changes of gas flow over time in the comparison example. FIG. 5 is a graph showing characteristics of a TFT having an oxide semiconductor film formed using the method of forming a thin-film in the comparison example. FIG. 6 is a graph showing a relationship between peak strength and wavelength in a CL spectrum in the comparison example. FIG. 7 is a graph comparatively showing peak strength in a CL spectrum above cathodes and between cathodes in the comparison example. FIG. 9 is a graph showing a relationship between measurement location of a thin-film formed on a substrate and sheet resistance in the comparison example.

As shown in FIG. 4, in a plasma process device of the comparison example a fixed flow of Ar gas and O₂ gas is constantly supplied to the processing chamber from the start of discharge until the end of discharge. FIG. 5 shows the results of measuring the characteristics of a TFT formed using the In-Ga-ZnO₄ film formed by the method of forming a thin-film of this comparison example. As shown in FIG. 5, the characteristics of a TFT having an In-Ga-ZnO₄ film E formed on substrate regions facing the targets (also called cathodes in the present specification) had substantially different characteristics than a TFT having an In-Ga-ZnO₄ film D formed on substrate regions facing between the targets (cathodes), with the latter shifting to the left in FIG. 5.

Next, the physical properties of the thin-film formed by the method of forming a thin-film of the comparison example were assessed by the cathode luminescence (CL) method. The light emitted when an electron beam illuminates a specimen is called cathode luminescence. The cathode luminescence method is a way to evaluate physical properties of a specimen from an image of the spectrum and spatial distribution of emitted light. The emitted light reflects band structures in defect regions, making it possible to evaluate the physical properties of microscopic regions from the strength of the emitted light and the spectral form.

The measuring conditions used for the cathode luminescence method were an acceleration voltage of 3 kV, a temperature of 32K, an SEM magnification of 1000×, a wavelength region of 200 to 100 nm, and a CCD as a detector. The composition ratio of In, Ga, and Zn, which are the targets, was 1:1:1. The film thickness of the thin-film was 100 nm, and the flow ratio of O₂ gas/(Ar gas+O₂ gas) was 4.5%.

As shown in FIG. 6, the results of measuring the relationship between the wavelength and peak strength of light of the In-Ga-ZnO₄ film E formed in substrate regions facing the targets and the In-Ga-ZnO₄ film D formed in substrate regions facing the gaps between the targets show that the wavelength where the strength of light for both film peaks is approximately 700 nm, but the value of the peak strength for both differed significantly. As shown in FIG. 7, the peak strength of light for the In-Ga-ZnO₄ film D is approximately 158, which is greater than the peak strength of light for the In-Ga-ZnO₄ film E, approximately 137.

As shown in FIG. 9, the sheet resistance of the In-Ga-ZnO₄ film D formed in the substrate regions facing the gaps between the targets (cathodes) is smaller than the sheet resistance of the In-Ga-ZnO₄ film E formed in the substrate regions facing the targets (cathodes).

As such, it was confirmed that the characteristics of the thin-film formed using the method of forming a thin-film in the comparison example has significant variation depending on whether the region where the thin-film is formed is a substrate region facing a gap between the targets (cathodes) or a substrate region facing the targets (cathodes).

Next, an actual conducted example of the present embodiment will be described with reference to FIGS. 8 and 10.

FIG. 8 is a graph comparatively showing peak strength in a CL spectrum above cathodes and between cathodes in the example. FIG. 10 is a graph showing a relationship between a measurement location of a thin-film formed on a substrate and sheet resistance in the example.

According to the method of forming a thin-film of the example, when peak strengths of lights were measured using the cathode luminescence method, as shown in FIG. 8, the In-Ga-ZnO₄ film E formed in substrate regions facing the targets had a peak strength of light of approximately 120, and the In-Ga-ZnO₄ film D formed in substrate regions facing the gaps between the targets had a peak strength of light of approximately 124, and thus there was a substantially smaller difference between the In-Ga-ZnO₄ film E and the In-Ga-ZnO₄ film D.

As shown in FIG. 10, the sheet resistance of the In-Ga-ZnO₄ film D formed in the substrate regions facing the gaps between the targets (cathodes) is generally the same as the sheet resistance of the In-Ga-ZnO₄ film E formed in the substrate regions facing the targets (cathodes).

As such, it was confirmed that the characteristics of the thin-film formed using the method of forming a thin-film according to the example were approximately the same regardless of whether the thin-film was formed in substrate regions facing the targets (cathodes) or substrate regions facing the gaps between the targets (cathodes), and that variation can be reduced.

### Embodiment 3

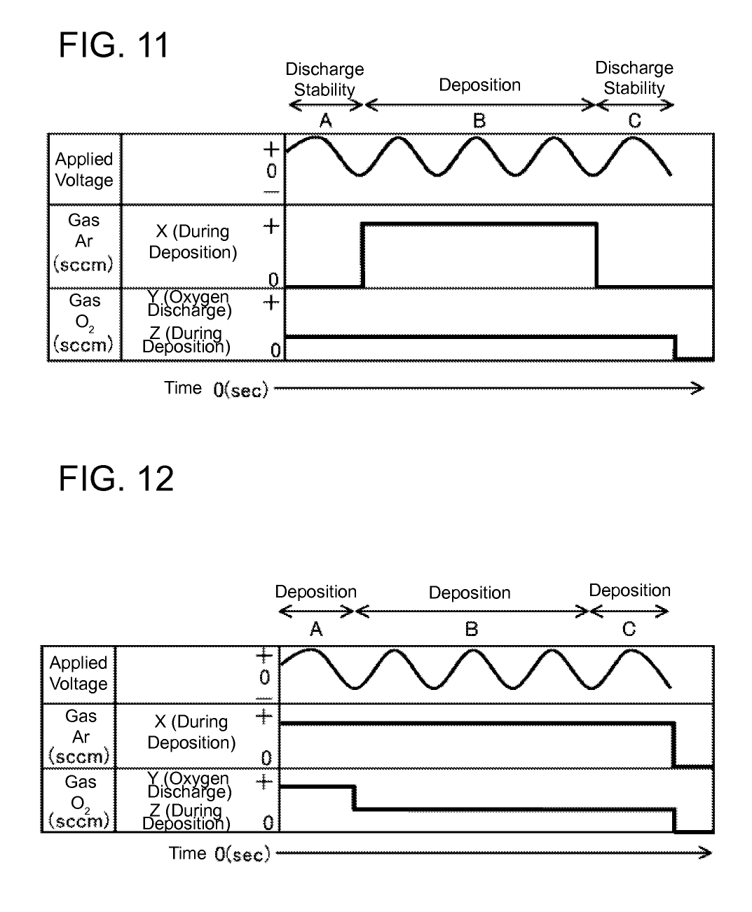

FIG. 11 shows Embodiment 3 of the present invention.

FIG. 11 is a graph showing changes of gas flow over time in Embodiment 3.

Embodiment 3 differs from Embodiment 2 in that the flow of O₂ gas is maintained at a consistent value throughout a discharge starting period A, normal deposition period B, and ending preparation period C, whereas in Embodiment 2 the flow of O₂ gas in the discharge starting period A and the ending preparation period C is greater than the flow of O₂ gas in the normal deposition period B.

In other words, as in Embodiments 1 and 2 described above, a control part 60 of the present embodiment controls a gas supply part 50 such that the flow ratio of O₂ gas to Ar gas in the discharge starting period A and ending preparation period C is larger than the flow ratio of O₂ gas to Ar gas in the normal deposition period B.

In particular, in the control part 60 of the present embodiment, as shown in FIG. 11, the flow of O₂ gas is maintained at a constant level in the discharge starting period A, normal deposition period B, and the ending preparation period C, whereas the flow of Ar gas in the discharge starting period A is less than the flow of Ar gas in the normal deposition period.

-Method of Forming a Thin-Film-

Next, a method will be explained to form a thin-film on the substrate 10 using a magnetron sputtering device 1 of the present embodiment.

The method of forming a thin-film in the present embodiment includes the discharge starting step conducted during the discharge starting period A, the normal deposition step conducted during the normal deposition period B, and the ending preparation step conducted during the ending preparation period C. Deposition is only conducted during the normal deposition step.

(Discharge Starting Step)

As shown in FIG. 11, in the discharge starting step, discharge at a target section 20 is started in a state in which a high vacuum is maintained while the control part 60 controls the gas supply part 50 in order to make the flow ratio of O₂ gas, the reactive gas, to Ar gas, the inert gas, greater than the flow ratio of O₂ gas to Ar gas in the normal deposition step.

In other words, as shown in FIG. 11, in the discharge starting period A, O₂ gas is supplied to the processing chamber 15 from the gas supply part 50 controlled by the control part 60 while the Ar gas is not being supplied.

Power is supplied to the target section 20 by applying a prescribed alternating current voltage from power sources 30, and a magnet section 40 is oscillated. The oscillation speed of the magnet section 40 is approximately 10 mm/s to 30 mm/s, for example. The substrate 10 that is held by a substrate holding part 11 is reciprocated in the M direction in FIG. 1.

In this way, a glow discharge is released between mutually adjacent targets 21 to generate plasma on the side of the substrate 10 near the target section 20. In this discharge starting step, the discharge state is stabilized with further ease because only the O₂ gas is supplied to a processing chamber 15 while the Ar gas is not being supplied to the processing chamber 15. The thin-film is not formed on the substrate 10 in this discharge starting step.

(Normal Deposition Step)

Next, in the normal deposition step, the flow ratio of the respective gases supplied by the gas supply part 50 is changed by the control part 60, while the reciprocating of the magnets 41 and substrate 10 and the discharge at the target section 20 are continued.

In other words, as shown in FIG. 11, in the normal deposition period B a prescribed flow of Ar gas is supplied to inside the processing chamber 15 from the gas supply part 50 controlled by the control part 60. However, O₂ gas is supplied to inside the processing chamber 15 in a flow that is the same as in the discharge starting step. Accordingly, in this normal deposition step, the flow ratio of O₂ gas to Ar gas is smaller than the flow ratio in the discharge starting step.

Thus, in the normal deposition step, deposition of the In-Ga-ZnO₄ film by sputtering is conducted efficiently and precisely in a discharge state that has been stabilized by the discharge starting step.

(Ending Preparation Step)

Next, in the ending preparation step, the flow ratio of the respective gases supplied by the gas supply part 50 is changed by the control part 60, while the reciprocating of the magnets 41 and substrate 10 and the discharge at the target section 20 are continued.

In other words, as shown in FIG. 11, in the ending preparation period C O₂ gas is supplied from the gas supply part 50 controlled by the control part 60 to the processing chamber 15, with the same flow of O₂ gas as the flow in the discharge starting step and normal deposition step, in a manner similar to the discharge starting step. This O₂ is supplied while the Ar gas is not being supplied. In other words, the flow of O₂ gas is maintained at a constant level.

In this way, in the ending preparation step, discharge is conducted at the target section 20 while only O₂ gas is supplied to the processing chamber 15 and while the flow ratio of O₂ gas to Ar gas is larger than the flow ratio of O₂ gas to Ar gas in the normal deposition step. This stabilizes the discharge state at the target section 20.

-Effects of Embodiment 3-

Therefore, according to Embodiment 3, the discharge state in the discharge starting period A and ending preparation period C can be stabilized by the flow ratio of O₂ gas to Ar gas in the discharge starting period A and ending preparation period C being larger than the same flow ratio in the normal deposition period B. As a result, variation in film quality of the thin-film can be suitably suppressed in regions of the substrate 10 facing the gaps between the targets 21 and regions of the substrate 10 facing the targets 21, resulting in the film quality of the thin-film formed on the entire substrate 10 by sputtering being able to be substantially increased

### Embodiment 4

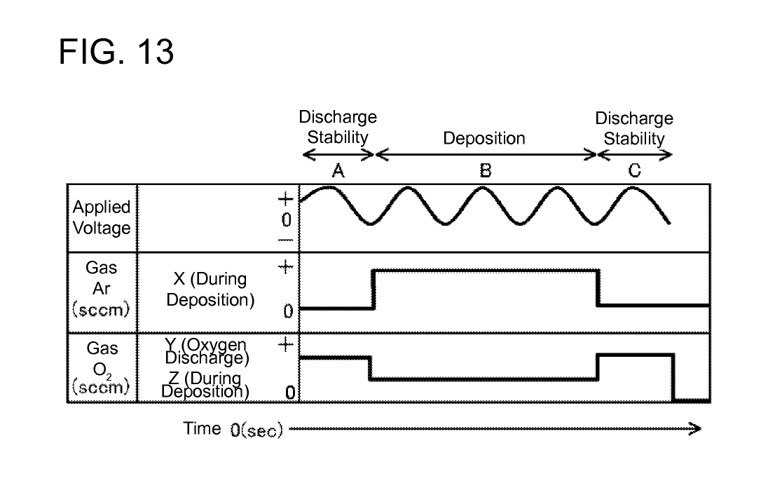

FIG. 12 shows Embodiment 4 of the present invention.

FIG. 12 is a graph showing changes of gas flow over time in Embodiment 4.

The present embodiment differs from Embodiment 1 in that the flow of O₂ gas in the discharge starting period A is only greater than the flow of O₂ gas in the normal deposition period B, whereas in Embodiment 1 the flow of O₂ gas in a discharge starting period A and ending preparation period C is greater than the flow of O₂ gas in a normal deposition period B.

In other words, a control part 60 of the present embodiment controls a gas supply part 50 such that the flow ratio of O₂ gas to Ar gas in the discharge starting period A is larger than the flow ratio of O₂ gas to Ar gas in the normal deposition period B.

In particular, the control part 60 of the present embodiment is configured such that, as shown in FIG. 12, the flow of O₂ gas in the discharge starting period A is greater than the flow of O₂ gas in the normal deposition period B and ending preparation period C, whereas the flow of Ar gas is maintained at a constant level in the discharge starting period A, normal deposition period B, ending preparation period C.

-Method of Forming a Thin-Film-

Next, a method will be explained to form a thin-film on a substrate 10 using a magnetron sputtering device 1 of the present embodiment.

The method of forming a thin-film in the present embodiment includes the discharge starting step conducted during the discharge starting period A, the normal deposition step conducted during the normal deposition period B, and the ending preparation step conducted during the ending preparation period C. Deposition is conducted throughout the entire discharge starting step, normal deposition step, and ending preparation step.

(Discharge Starting Step)

In the discharge starting step, discharge at a target section 20 is started in a state in which a high vacuum is maintained while the control part 60 controls the gas supply part 50 in order to make the flow ratio of O₂ gas, the reactive gas, to Ar gas, the inert gas, greater than the flow ratio of O₂ gas to Ar gas in the normal deposition step, which is conducted after the discharge starting step.

In other words, as shown in FIG. 12, in the discharge starting period A, a prescribed flow of Ar gas is supplied to inside a processing chamber 15 from the gas supply part 50, which is controlled by the control part 60. The O₂ gas is supplied into the processing chamber 15 in a flow that is greater than the flow of O₂ gas in the normal deposition step. The flow of Ar gas is maintained at a constant level throughout the discharge starting step, normal deposition step, and ending preparation step.

Power is supplied to the target section 20 by applying a prescribed alternating current voltage from power sources 30, and a magnet section 40 is oscillated. The oscillation speed of the magnet section 40 is approximately 10 mm/s to 30 mm/s, for example. The substrate 10 that is held by a substrate holding part 11 is reciprocated in the M direction in FIG. 1.

In this way, a glow discharge is released between mutually adjacent targets 21 to generate plasma on the side of the substrate 10 near the target section 20. In this discharge starting step, the flow ratio of O₂ gas to Ar gas is larger than the same flow ratio in the normal deposition step, and thus the discharge state is stabilized with ease. Thus, an In-Ga-ZnO₄ thin-film is formed on the substrate 10.

(Normal Deposition Step)

Next, in the normal deposition step, the flow ratio of the respective gases supplied by the gas supply part 50 is changed by the control part 60, while the reciprocating of the magnets 41 and substrate 10 and the discharge at the target section 20 are continued in a similar manner to the discharge starting step.

In other words, as shown in FIG. 12, in the normal deposition period B, Ar gas is supplied to inside the processing chamber 15 from the gas supply part 50 controlled by the control part 60 with the same flow as the discharge starting step. However, O₂ gas is supplied to inside the processing chamber 15 with a flow that is less than the discharge starting step. Accordingly, in this normal deposition step, the flow ratio of O₂ gas to Ar gas is smaller than the flow ratio in the discharge starting step.

Thus, in the normal deposition step, deposition of the In-Ga-ZnO₄ film by sputtering is conducted efficiently and precisely in a discharge state that has been stabilized by the discharge starting step.

(Ending Preparation Step)

Next, in the ending preparation step, the flow ratio of the respective gases supplied by the gas supply part 50 is maintained at a constant level, while the reciprocating of the magnets 41 and substrate 10 and the discharge at the target section 20 are continued in a similar manner to the normal deposition step.

In other words, as shown in FIG. 12, in the ending preparation period C, Ar gas is supplied to inside the processing chamber 15 from the gas supply part 50 controlled by the control part 60 with the same flow as the discharge starting step and normal deposition step. The O₂ gas is supplied to inside the processing chamber 15 with the same flow as the flow of O₂ gas in the normal deposition step.

Afterwards, as shown in FIG. 12, the supplying of Ar gas and O₂ gas to the processing chamber 15 is stopped and deposition processing ends.

-Effects of Embodiment 4-

Therefore, according to Embodiment 4, the discharge state in the discharge starting period A can be stabilized by the flow ratio of O₂ gas to Ar gas in the discharge starting period A being larger than the same flow ratio in the normal deposition period B. As a result, variation in film quality of the thin-film can be suitably suppressed in regions of the substrate 10 facing the gaps between the targets 21 and regions of the substrate 10 facing the targets 21, resulting in the film quality of the thin-film formed on the entire substrate 10 by sputtering being able to be substantially increased.

### Embodiment 5

FIG. 13 shows Embodiment 5 of the present invention.

FIG. 13 is a graph showing changes of gas flow over time in Embodiment 5.

The present embodiment differs from Embodiment 2 in that a relatively small flow of Ar gas is supplied to a processing chamber 15 in a discharge starting period A and ending preparation period C, whereas in Embodiment 2 the Ar gas in these periods A and C was not being supplied to the processing chamber 15.

In other words, a control part 60 of the present embodiment controls a gas supply part 50 such that the flow ratio of O₂ gas to Ar gas in the discharge starting period A and ending preparation period C is larger than the flow ratio of O₂ gas to Ar gas in a normal deposition period B.

In particular, the control part 60 of the present embodiment is configured to control the gas supply part 50 such that, as shown in FIG. 13, Ar gas is supplied to the processing chamber 15 in the discharge starting period A and ending preparation period C with a flow that is less than the flow of Ar gas in the normal deposition period B, whereas O₂ is supplied to the processing chamber 15 in the discharge starting period A and ending preparation period C with a flow that is greater than the flow of O₂ gas in the normal deposition period B.

-Method of Forming a Thin-Film-

Next, a method will be explained to form a thin-film on a substrate 10 using a magnetron sputtering device 1 of the present embodiment.

The method of forming a thin-film in the present embodiment includes the discharge starting step conducted during the discharge starting period A, the normal deposition step conducted during the normal deposition period B, and the ending preparation step conducted during the ending preparation period C. Deposition is only conducted during the normal deposition step.

(Discharge Starting Step)

As shown in FIG. 13, in the discharge starting step, discharge at a target section 20 is started in a state in which a high vacuum is maintained while the control part 60 controls the gas supply part 50 in order to make the flow ratio of O₂ gas to Ar gas greater than the flow ratio of O₂ gas to Ar gas in the normal deposition step.

In other words, as shown in FIG. 13, in the discharge starting period A, O₂ gas is supplied from the gas supply part 50 controlled by the control part 60 to the processing chamber 15 with a flow of Ar gas that is less than the flow of Ar gas in the normal deposition period B, whereas O₂ gas is supplied to the processing chamber 15 with a flow that is greater than the flow of O₂ gas in the normal deposition period.

Power is supplied to the target section 20 by applying a prescribed alternating current voltage from power sources 30, and a magnet section 40 is oscillated. The oscillation speed of the magnet section 40 is approximately 10 mm/s to 30 mm/s, for example. The substrate 10 that is held by a substrate holding part 11 is reciprocated in the M direction in FIG. 1.

In this way, a glow discharge is released between mutually adjacent targets 21 to generate plasma on the side of the substrate 10 near the target section 20. In this discharge starting step, the discharge state is stabilized with further ease because only the O₂ gas is supplied to a processing chamber 15 while the Ar gas is not being supplied to the processing chamber 15. The thin-film is not formed on the substrate 10 in this discharge starting step.

(Normal Deposition Step)

Next, in the normal deposition step, the flow ratio of the respective gases supplied by the gas supply part 50 is changed by the control part 60, while the reciprocating of the magnets 41 and substrate 10 and the discharge at the target section 20 are continued.

In other words, as shown in FIG. 13, in the normal deposition period B Ar gas is supplied to inside the processing chamber 15 from the gas supply part 50 controlled by the control part 60, with a flow that is greater than the flow of Ar gas in the discharge starting step. The O₂ gas is supplied to inside the processing chamber 15 with a flow that is less than the flow of O₂ in the discharge starting step. Accordingly, in this normal deposition step, the flow ratio of O₂ gas to Ar gas is smaller than the flow ratio in the discharge starting step.

Thus, in the normal deposition step, deposition of the In-Ga-ZnO₄ film by sputtering is conducted efficiently and precisely in a discharge state that has been stabilized by the discharge starting step.

(Ending Preparation Step)

Next, in the ending preparation step, the flow ratio of the respective gases supplied by the gas supply part 50 is changed by the control part 60, while the reciprocating of the magnets 41 and substrate 10 and the discharge at the target section 20 are continued.

In other words, as shown in FIG. 13, in the ending preparation period C, Ar gas is supplied from the gas supply part 50 controlled by the control part 60 to the processing chamber 15 with a flow that is less than the flow of Ar gas in the normal deposition step, whereas O₂ gas is supplied to inside the processing chamber 15 with a flow that is greater than the flow of O₂ gas in the discharge starting step, as in the discharge starting step.

In this way, in the ending preparation step, discharge is conducted at the target section 20 while the flow ratio of O₂ gas to Ar gas is larger than the flow ratio of O₂ gas to Ar gas in the normal deposition step. This stabilizes the discharge state at the target section 20.

-Effects of Embodiment 5-

Therefore, according to Embodiment 5, the discharge state in the discharge starting period A and ending preparation period C can be stabilized by the flow ratio of O₂ gas to Ar gas in the discharge starting period A and ending preparation period C being larger than the same flow ratio in the normal deposition period B. As a result, variation in film quality of the thin-film can be suitably suppressed in regions of the substrate 10 facing the gaps between the targets 21 and regions of the substrate 10 facing the targets 21, resulting in the film quality of the thin-film formed on the entire substrate 10 by sputtering being able to be substantially increased.

The present invention is not limited to Embodiments 1 to 5, and includes configurations in which Embodiments 1 to 5 are appropriately combined.

### INDUSTRIAL APPLICABILITY

As described above, the present invention is useful for a method of forming a thin-film.

### Description of Reference Characters

1 magnetron sputtering device
10 substrate
11 substrate holding part
15 processing chamber
20 target section
21 target
30 alternating current power source
40 magnet section
41 magnet
50 gas supply part
60 control part

1. A method of forming a thin-film, comprising:
a normal deposition step of depositing a thin-film on a substrate in a processing chamber by performing discharge among a plurality of targets that are arranged parallel to the substrate at prescribed gaps, and by providing an inert gas and a reactive gas to the processing chamber, said targets constituting a target section that is arranged facing the substrate to be processed, the discharge being performed when a magnet section is reciprocated along said target section; and
a discharge starting step of starting discharge in the target section prior to the normal deposition step, in a state in which a flow ratio of the reactive gas to the inert gas is larger than a flow ratio of the reactive gas to the inert gas during the normal deposition step.

2. The method of forming a thin-film according to claim 1,
wherein a flow of the reactive gas in the discharge starting step is larger than the flow of the reactive gas in the normal deposition step, and a flow of the inert gas in the discharge starting step and in the normal deposition step is maintained at a constant level.

3. The method of forming a thin-film according to claim 1,
wherein a flow of the reactive gas in the discharge starting step is larger than the flow of the reactive gas in the normal deposition step, and a flow of the inert gas in the discharge starting step is less than the flow of the inert gas in the normal deposition step.

4. The method of forming a thin-film according to claim 3,
wherein the reactive gas is provided in the discharge starting step while the inert gas is not provided to the processing chamber.

5. The method of forming a thin-film according to claim 1,
wherein a flow of the reactive gas in the discharge starting step and the normal deposition step is maintained at a constant level, and a flow of the inert gas in the discharge starting step is less than the flow of the inert gas in the normal deposition step.

6. The method of forming a thin-film according to claim 1, further comprising: an ending preparation step of performing discharge on the target section, after the normal deposition step, in a state in which the flow ratio of the reactive gas to the inert gas is larger than the flow ratio of the reactive gas to the inert gas in the normal deposition step.

7. The method of forming a thin-film according to claim 1,
wherein the thin-film is an oxide semiconductor film.

8. The method of forming a thin-film according to claim 7,
wherein the oxide semiconductor film is made of In-Ga-ZnO₄.

9. The method of forming a thin-film according to claim 1,
wherein there is no flow of the inert gas in the discharge starting step.
